(19) United States
(12) Patent Application Publication
(10) Pub. No.: US 2025/0226208 A1
(43) Pub. Date: Jul. 10, 2025

(54) METHODS FOR PROTECTING A PERIPHERAL EDGE AND BACKSIDE OF A SEMICONDUCTOR SUBSTRATE

(71) Applicant: Tokyo Electron Limited, Tokyo (JP)

(72) Inventors: Shan Hu, Albany, NY (US); Peter D'Elia, Albany, NY (US); Scott Lefevre, Albany, NY (US)

(21) Appl. No.: 18/407,527

(22) Filed: Jan. 9, 2024

(51) Int. Cl. H01L 21/02; H01L 21/306; H01L 21/3065

(52) U.S. Cl. CPC H01L 21/02282; H01L 21/0206; H01L 21/02115; H01L 21/0212; H01L 21/30604; H01L 21/3065

(57) ABSTRACT

Various embodiments of processes and methods are provided herein for processing a semiconductor substrate. More specifically, improved processes and methods are provided for preventing damage to, or contamination on, a peripheral edge region and/or backside of a semiconductor substrate as the frontside of the substrate undergoes processing. In the disclosed embodiments, a sacrificial film is spin-on deposited within the peripheral edge region and/or along the backside surface before a process is performed on the frontside of the substrate. The sacrificial film protects the peripheral edge region and/or backside of the substrate and is removed from the substrate after processing.

### BACKGROUND

The present disclosure relates to the processing of semiconductor substrates. In particular, it provides novel methods for protecting the peripheral edge and backside of a semiconductor substrate during processing.

During an integrated circuit (IC) fabrication process, a wide variety of processing steps, such as film deposition, patterning, etching, ion implantation, cleaning, etc., may be performed on a semiconductor substrate to form various film layers, semiconductor structures and active circuit components within a center region of the substrate. The center region of the substrate extends from the center of the substrate to a peripheral edge region (otherwise referred to as a bevel region or beveled edge). The bevel region of the substrate encompasses outer annular portions of the frontside and backside surfaces, as well as the side edge surface of the substrate. Unlike the center region, the bevel region contains no semiconductor structures or active circuit components. However, the bevel region is typically exposed to the same chemicals, process gases, radiation, plasma, etc., used to process the center region of the substrate. Some of these processes may damage, or generate contamination and defects on, the bevel region and/or backside surface of the substrate.

Accumulation of particles and peeling at the bevel region and on the backside surface of the substrate creates contamination that can lead to yield loss. In some cases, a bevel etch or bevel clean process may be performed to remove the contaminants within the bevel region of the substrate. Cleaning processes have also been developed to clean the backside surface of the substrate. However, such cleaning processes cannot prevent damage from occurring within the bevel region or backside surface of the substrate, such as backside damage caused by an electrostatic or vacuum wafer chuck or bevel damage caused by a wet or dry etch process. Furthermore, some cleaning processes may not completely remove contamination from the bevel region due to the contour of the bevel region, the non-uniformity of film layers and other contaminants deposited on the bevel surface and the imprecise centering of the substrate within the cleaning tool.

A need, therefore, remains for improved methods for protecting the peripheral edge region and/or backside of the substrate during subsequent processing.

### SUMMARY

The present disclosure provides improved processes and methods for protecting the peripheral edge region and/or the backside of a semiconductor substrate. More specifically, the present disclosure provides improved methods for preventing damage to, or contamination on, the peripheral edge region and/or the backside of a semiconductor substrate as the frontside of the substrate undergoes processing.

In the disclosed embodiments, a sacrificial film is spin-on deposited within the peripheral edge region and/or along a backside surface of a semiconductor substrate before a process is performed on the frontside of the substrate. Although intended for processing a frontside center region of the substrate, the process may cause damage to, or generate contamination and defects on, the peripheral edge region and/or the backside of the substrate. Examples of processes that may damage or generate contamination on the peripheral edge region and/or the backside of the substrate include, but are not limited to etch processes, deposition processes, lithography processes, chemical mechanical polishing (CMP) processes, etc. Once the process is complete, a cleaning process is performed to remove the sacrificial film and any contaminants or defects adhered thereto.

According to one embodiment, a method is provided herein for processing a semiconductor substrate. In the disclosed method, a sacrificial film is used to protect the peripheral edge region and/or the backside surface of a semiconductor substrate during various processes, including for example, an etch process and a deposition process.

The method may begin by receiving a semiconductor substrate having a frontside surface, a backside surface, a side edge surface, a peripheral edge region and a frontside center region. As described further herein, the peripheral edge region includes the side edge surface and annular portions of the frontside surface and the backside surface adjacent to the side edge surface. The frontside center region extends from a center (c) of the frontside surface to the peripheral edge region.

The method further includes spin-on depositing a sacrificial film within the peripheral edge region of the semiconductor substrate using a spin-on deposition process. In some embodiments, the spin-on deposition process may coat the peripheral edge region with the sacrificial film. In other embodiments, the spin-on deposition process may coat the peripheral edge region and (at least a portion of) the backside surface with the sacrificial film. The sacrificial film can be spin-on deposited using a wide variety of liquid materials, processing chambers and nozzle configurations, as described in more detail below.

The method further includes processing the semiconductor substrate after spin-on depositing the sacrificial film. In various embodiments, the semiconductor substrate may be processed by: (1) etching an exposed surface of at least one material layer provided within the frontside center region of the semiconductor substrate, or (2) depositing at least one material layer within the frontside center region of the semiconductor substrate. Thus, in the various embodiments, the sacrificial film may protect the peripheral edge region and/or the backside surface of the semiconductor substrate from damage during etching, or particles deposited onto the sacrificial film during depositing. In some embodiments, the method may further include removing the sacrificial film from the peripheral edge region and/or the backside surface of the semiconductor substrate after processing the semiconductor substrate.

In some embodiments, the sacrificial film may be spin-on deposited by dispensing a liquid material within the peripheral edge region of the semiconductor substrate that is not removed during said processing. For example, the liquid material may be dispensed by dispensing a fluoropolymer material, a spin-on metal material, a spin-on glass (SOG) material, a spin-on carbon (SOC) material or a spin-on silicon carbide (SiC) material within the peripheral edge region of the semiconductor substrate.

A wide variety of processing chambers and nozzle configurations can be used to dispense the liquid material within the peripheral edge region of a semiconductor substrate. In some embodiments, the liquid material may be dispensed within a processing chamber comprising a frontside bevel nozzle. In such embodiments, the frontside bevel nozzle may dispense the liquid material onto the annular portion of the frontside surface while spinning the semiconductor substrate at a rotational speed, which causes the liquid material to wrap around the side edge surface of the semiconductor substrate to coat the annular portion of the backside surface. In other embodiments, the liquid material may be dispensed within a processing chamber comprising a backside bevel nozzle. In such embodiments, the backside bevel nozzle may dispense the liquid material onto the annular portion of the backside surface while spinning the semiconductor substrate at a rotational speed, which causes the liquid material to wrap around the side edge surface of the semiconductor substrate to coat the annular portion of the frontside surface.

In other embodiments, the sacrificial film may be spin-on deposited by dispensing a liquid material within the peripheral edge region and on the backside surface of the semiconductor substrate. For example, the liquid material may be dispensed by dispensing a fluoropolymer material, a spin-on metal material, a spin-on glass (SOG) material, a spin-on carbon (SOC) material or a spin-on silicon carbide (SiC) material within the peripheral edge region and on the backside surface of the semiconductor substrate.

A wide variety of processing chambers and nozzle configurations can be used to dispense the liquid material within the peripheral edge region and on the backside surface of the semiconductor substrate. In some embodiments, the liquid material may be dispensed within a processing chamber comprising a backside nozzle. In such embodiments, the backside nozzle may dispense the liquid material onto the backside surface of the semiconductor substrate near the center of the semiconductor substrate while spinning the semiconductor substrate at a rotational speed, which causes the liquid material to cover the backside surface and wrap around the side edge surface of the semiconductor substrate to coat the annular portion of the frontside surface.

A wide variety of processes can be performed on the semiconductor substrate after spin-on depositing the sacrificial film. For example, an etch process, deposition process, lithography process, CMP process, etc., can be performed on the frontside of the substrate after the sacrificial film is spin-on deposited. Other processes can also be performed, as is known in the art. Depending on the process performed, the sacrificial film may protect the peripheral edge region and/or the backside surface from damage or contamination that may occur during the processing step.

In some embodiments, the semiconductor substrate may be processed by providing the semiconductor substrate within a processing chamber having a chuck configured to support one or more surfaces of the substrate, such as a mechanical chuck, an electrostatic chuck or a vacuum chuck. As noted above, electrostatic and vacuum chucks may damage the semiconductor substrate when the substrate is removed from the chuck. By depositing a sacrificial film within the peripheral edge region and/or along the backside surface of the semiconductor substrate, the sacrificial film disclosed herein may protect the peripheral edge region and/or the backside surface from damage caused by the chuck.

In other embodiments, the semiconductor substrate may be processed by etching an exposed surface of at least one material layer provided within the frontside center region of the semiconductor substrate using a wet or dry etch process, which exposes the frontside center region and the peripheral edge region of the semiconductor substrate to an etchant chemical or gas. In such embodiments, the sacrificial film may act as a hard mask to protect the peripheral edge region of the semiconductor substrate from being etched by the etchant chemical or gas during the wet or dry etch process.

The sacrificial film material chosen to protect the peripheral edge region during the wet or dry etch process may generally depend on the etchant chemical(s) or gas(es) used during the wet or dry etch process. In general, the sacrificial film material chosen to protect the peripheral edge region during the wet or dry etch process may be deposited by dispensing a liquid material within the peripheral edge region of the semiconductor substrate that is not removed by the etchant chemical or gas. Examples of liquid materials that are not removed by various etchant chemicals and gases include, but are not limited to, fluoropolymer materials, spin-on metal materials, spin-on glass (SOG) materials, spin-on carbon (SOC) materials and a spin-on silicon carbide (SiC) materials. In some embodiments, the method may further include removing the sacrificial film from the peripheral edge region of the semiconductor substrate after said etching. For example, the method may remove the sacrificial film by dispensing a cleaning solution onto the semiconductor substrate to remove the sacrificial film from the peripheral edge region.

In yet other embodiments, the semiconductor substrate may be processed by depositing at least one material layer within the frontside center region of the semiconductor substrate using a dry deposition process, which exposes the frontside center region and the peripheral edge region of the semiconductor substrate to at least one process gas. In such embodiments, the sacrificial film may protect the peripheral edge region and/or the backside surface of the semiconductor substrate from gas particles that may adhere to the sacrificial film during the dry deposition process.

In some embodiments, the sacrificial film used to protect the peripheral edge region and/or the backside surface from gas particles (or contamination) during the dry deposition process may be spin-on deposited by dispensing a liquid material within the peripheral edge region and at least a portion of the backside surface of the semiconductor substrate. More specifically, the sacrificial film may be spin-on deposited by: (a) dispensing a liquid material onto the semiconductor substrate while spinning the semiconductor substrate at a rotational speed, which causes the liquid material to cover the peripheral edge region and at least a portion of the backside surface of the semiconductor substrate, and (b) heat treating the semiconductor substrate to solidify the liquid material and form the sacrificial film within the peripheral edge region and on the at least a portion of the backside surface. The sacrificial film may protect the peripheral edge region and at least a portion of the backside surface of the semiconductor substrate from gas particles that adhere to the sacrificial film during the dry deposition process. Examples of sacrificial film materials that can be used to protect the peripheral edge region and at least a portion of the backside surface from gas particles include, but are not limited to, fluoropolymer materials, spin-on metal materials, spin-on glass (SOG) materials, spin-on carbon (SOC) materials and spin-on silicon carbide (SiC) materials.

In some embodiments, the method may further include removing the sacrificial film and the gas particles that adhere to the sacrificial film during the dry deposition process. For example, the method may remove the sacrificial film by dispensing a cleaning solution onto the semiconductor substrate to remove the sacrificial film and the gas particles that adhere to the sacrificial film during the dry deposition process.

Various embodiments of methods are provided herein for processing a substrate, and more specifically, for providing a sacrificial film to protect a peripheral edge region and/or backside of the substrate during subsequent processing. Of course, the order of discussion of the different steps as described herein has been presented for the sake of clarity. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed inventions. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1A is a top down view of a semiconductor substrate having a frontside surface, a backside surface (shown in FIG. 1C), a side edge surface, a peripheral edge region and a frontside center region.

FIG. 1B is a side view of the semiconductor substrate shown in FIGS. 1A and 1C, illustrating the side edge surface of the substrate.

FIG. 1C is a bottom up view of the semiconductor substrate having a frontside surface (shown in FIG. 1A), a backside surface, a side edge surface, a peripheral edge region and a backside center region.

FIG. 2A is a side cross-sectional view of the semiconductor substrate shown in FIGS. 1A-1C, illustrating the portion of the substrate shown in the box 160 of FIG. 1B.

FIG. 2B provides an example of damage that may occur on the peripheral edge region of the semiconductor substrate W after an etch process is performed on the substrate.

FIG. 2C provides an example of contamination that may be generated on the peripheral edge region and/or along the backside surface of the semiconductor substrate W after a deposition process is performed on the substrate.

FIG. 3 illustrates an example process flow that utilizes the techniques described herein to prevent damage to, or contamination on, the peripheral edge region and/or the backside surface of a semiconductor substrate as the frontside of the substrate undergoes processing.

FIG. 4A is a side cross-sectional view of a semiconductor substrate, illustrating a sacrificial film deposited within a peripheral edge region of the substrate using a frontside bevel nozzle.

FIG. 4B is a side cross-sectional view of a semiconductor substrate, illustrating a sacrificial film deposited within a peripheral edge region of the substrate using a backside bevel nozzle.

FIG. 4C is a side cross-sectional view of a semiconductor substrate, illustrating a sacrificial film deposited onto a backside surface and within the peripheral edge region of the substrate using a backside nozzle.

FIG. 5 illustrates one embodiment of a processing chamber that can be used to spin-on deposit a sacrificial film within a peripheral edge region of a semiconductor substrate (W), as shown in FIGS. 4A-4B.

FIG. 6 illustrates another embodiment of a processing chamber that can be used to spin-on deposit a sacrificial film within a peripheral edge region and/or backside of a semiconductor substrate (W), as shown in FIGS. 4A-4C.

FIG. 7 is a flowchart diagram illustrating one embodiment of a method that utilizes the techniques described herein to process a semiconductor substrate.

FIG. 8 is a flowchart diagram illustrating another embodiment of a method that utilizes the techniques described herein to process a semiconductor substrate.

FIG. 9 is a flowchart diagram illustrating yet another embodiment of a method that utilizes the techniques described herein to process a semiconductor substrate.

### DETAILED DESCRIPTION

The present disclosure provides improved processes and methods for protecting the peripheral edge region and/or the backside of a semiconductor substrate. More specifically, the present disclosure provides improved methods for preventing damage to, or contamination on, the peripheral edge region and/or backside of a semiconductor substrate as the frontside of the substrate undergoes processing.

In the disclosed embodiments, a sacrificial film is spin-on deposited within the peripheral edge region and/or along a backside surface of a semiconductor substrate before a process is performed on the frontside of the substrate. Although intended for processing a frontside center region of the substrate, the process may cause damage to, or generate contamination and defects on, the peripheral edge region and/or the backside of the substrate. Examples of processes that may damage or generate contamination on the peripheral edge region and/or the backside of the substrate include, but are not limited to etch processes, deposition processes, lithography processes, chemical mechanical polishing (CMP) processes, etc. Once the process is complete, a cleaning process is performed to remove the sacrificial film and any contaminants or defects adhered thereto.

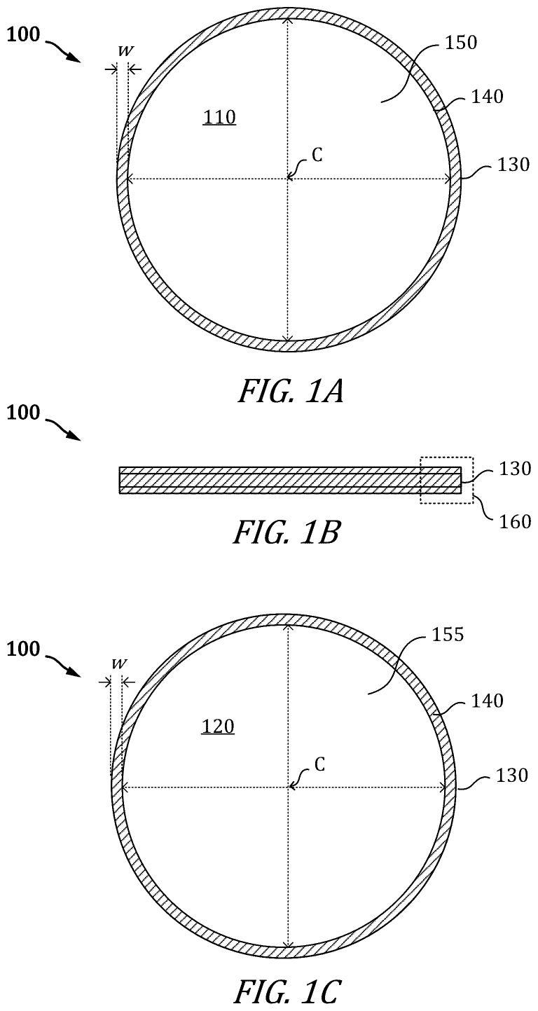

Turning now to the Drawings, a semiconductor substrate 100 (or wafer, W) is illustrated in FIGS. 1A-1C. The semiconductor substrate 100 may be any substrate for which the use of patterned features is desirable. In one embodiment, semiconductor substrate 100 may be a semiconductor substrate having one or more semiconductor processing layers formed thereon. For example, semiconductor substrate 100 may be a substrate that has been subjected to multiple semiconductor processing steps which yield a wide variety of structures and layers, all of which are known in the substrate processing art. In another embodiment, the semiconductor substrate 100 may be a silicon substrate or other bulk substrate comprising a layer of semi-conductive material. The semiconductor substrate 100 shown in FIGS. 1A-1C is disc-shaped and relatively thin (e.g., 275 μm to 775 μm). The diameter of the semiconductor substrate 100 may range between approximately 25 mm and 300 mm or even larger.

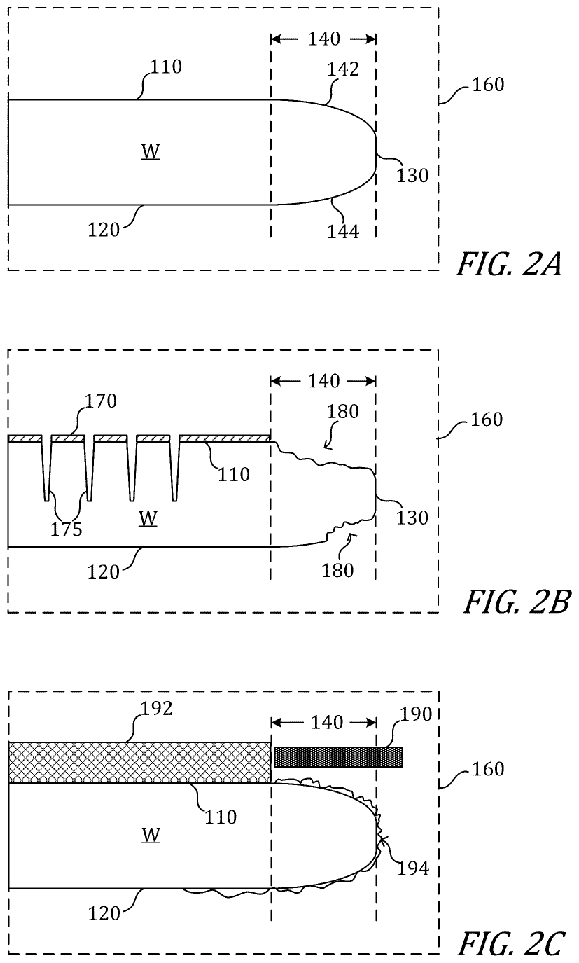

As shown in FIGS. 1A-1C, semiconductor substrate 100 has a frontside surface 110, a backside surface 120, a side edge surface 130, a peripheral edge region 140, a frontside center region 150 on the frontside surface 110 and a backside center region 155 on the backside surface 120. The peripheral edge region 140 of the semiconductor substrate 100 (otherwise referred to as the bevel region) includes an outer annular portion of the frontside surface 110, the side edge surface 130, and an outer annular portion of the backside surface 120. The annular portions of the frontside surface 110 and the backside surface 120 are located at the periphery of the semiconductor substrate 100 adjacent to the side edge surface 130. A width (w) of the annular portions of the frontside surface 110 and the backside surface 120 is small compared to the diameter (e.g., 300 mm) of the semiconductor substrate 100. For example, the width (w) may range between approximately 1-5 mm. In some embodiments, the annular portions of the frontside surface 110 and the backside surface 120 may be rounded, as shown in FIG. 1B and FIG. 2A, or beveled with planar beveled edges. For the sake of simplicity, rounded and beveled contours are considered herein to be beveled edges.

As shown in FIG. 1A, the frontside center region 150 on the frontside surface 110 of the semiconductor substrate 100 extends from the center (C) of the semiconductor substrate 100 to the peripheral edge region 140. A wide variety of processing steps, such as film deposition, patterning, etching, ion implantation, cleaning, etc., may be performed on the frontside surface 110 of the semiconductor substrate 100 to form various film layers, semiconductor structures and active circuit components within the frontside center region 150. In other words, the frontside center region 150 is the region of the semiconductor substrate 100 where semiconductor structures, or active circuit components, are typically formed. Unlike the frontside center region 150, no semiconductor structures or active circuit components are formed within the peripheral edge region 140 (or bevel region) of the semiconductor substrate 100.

As shown in FIG. 1C, the backside center region 155 on the backside surface 120 of the semiconductor substrate 100 also extends from the center (C) of the semiconductor substrate 100 to the peripheral edge region 140. In some IC fabrication processes, the backside surface 120 of the semiconductor substrate 100 may be subjected to various processing steps to deposit film layers on the backside surface 120 (e.g., to control wafer planarity), clean the backside surface 120 (e.g., to remove contaminants) or perform other backside wafer processing.

For example, through silicon vias (TSVs) are utilized in some integrated circuits to connect circuit components formed on the frontside surface 110 of the semiconductor substrate 100 to metal lines formed on the backside surface 120 of the semiconductor substrate 100. TSVs are typically formed by performing a dry etch process on the frontside surface 110 to etch the TSVs partially through the semiconductor substrate 100. Thereafter, a metallization process is performed on the frontside surface 110 to deposit metal material(s) within the TSVs. After etching and metallization processes are performed on the frontside surface 110, the semiconductor substrate 100 is flipped upside down and the backside surface 120 is ground down to expose the TSVs before additional processing is performed on the backside surface 120 to connect the exposed TSVs to metal lines subsequently formed on the backside.

FIG. 2A depicts a portion of the semiconductor substrate 100 shown in the box 160 of FIG. 1B, illustrating further details of the peripheral edge region 140. As shown in FIG. 2A, the peripheral edge region 140 of the semiconductor substrate 100 may have a beveled edge including a front beveled edge 142 which slopes from the frontside surface 110 to the side edge surface 130, and a back beveled edge 144 which slopes from the backside surface 120 to the side edge surface 130. Although the beveled edge is illustrated as having a rounded contour, the beveled edge may alternatively include angled beveled contours, as is known in the art.

As noted above in the Background Section, the peripheral edge region 140 (or beveled region) of the semiconductor substrate 100 is typically exposed to the same chemicals, process gases, radiation, plasma, etc., used to process the frontside center region 150 of the substrate. Some of these processes may damage, or generate contamination and defects on, the peripheral edge region 140 and/or along the backside surface 120 of the semiconductor substrate 100. For example, the backside surface 120 may be damaged when removed from an electrostatic or vacuum wafer chuck.

The peripheral edge region 140 may also be damaged when an etch process is performed on the frontside surface 110. During a TSV dry etch process, for example, the majority of the substrate surface is coated with a photo resist/hard mask, while the portions to be etched are exposed to etch gases. The TSV dry etch process is a long etch process, which can be as long as tens of minutes. Unlike the frontside center region 150, the peripheral edge region 140 and the backside surface 120 of the semiconductor substrate 100 are not covered by the photo resist/hard mask during the etch process. Because the peripheral edge region 140 and backside surface 120 of the substrate are also exposed to the etch gases used to etch the TSVs, significant damage may occur within these regions, as shown in FIG. 2B.

FIG. 2B illustrates the damage that may occur within the peripheral edge region 140 of the semiconductor substrate 100 during a dry etch process (e.g., a TSV dry etch process). Prior to etch, the frontside surface 110 of the semiconductor substrate 100 is coated with a photo resist/hard mask layer 170, which is patterned to expose portions of the underlying substrate. When the frontside surface 110 is subsequently exposed to a dry etch process, the etch gases used for etching the exposed portions of the substrate to form the TSVs 175 partially through the substrate may damage the peripheral edge region 140. For example, the etch gases may cause damage 180 to the unprotected front beveled edge 142 and/or back beveled edge 144, as shown in FIG. 2B.

Other processes performed on the frontside of the substrate may result in an accumulation of film layers or particles within the peripheral edge region 140. As layers upon layers are deposited and etched to create semiconductor structures on the frontside of the substrate, the typically smooth beveled edges withing the peripheral edge region 140 can become pitted or rough and films or other processing residue can accumulate. The contamination accumulated within the peripheral edge region 140 can peel and flake off during subsequent processing steps, sometimes migrating to active areas of the substrate, which may cause defects and affect yield.

FIG. 2C provides an example of contamination that may be generated on the peripheral edge region 140 and/or along the backside surface 120 of the semiconductor substrate 100 during an example dry deposition process. During a chemical vapor deposition (CVD) process or atomic layer deposition (ALD) process, for example, a ring-shaped body 190 can be positioned above the semiconductor substrate 100 to shield the peripheral edge region 140 when depositing various material layer(s) 192 within the frontside center region 150 of the substrate. Although the ring-shaped body 190 prevents the material layer(s) 192 from being deposited within the peripheral edge region 140, the process gases used in the dry deposition process may freely move around and land on the peripheral edge region 140 and/or along the backside surface 120 of the semiconductor substrate 100. The gas particles that land on and adhere to the peripheral edge region 140 and/or along the backside surface 120 of the semiconductor substrate 100 may generate contamination 194, which may be difficult to remove during subsequent cleaning processes.

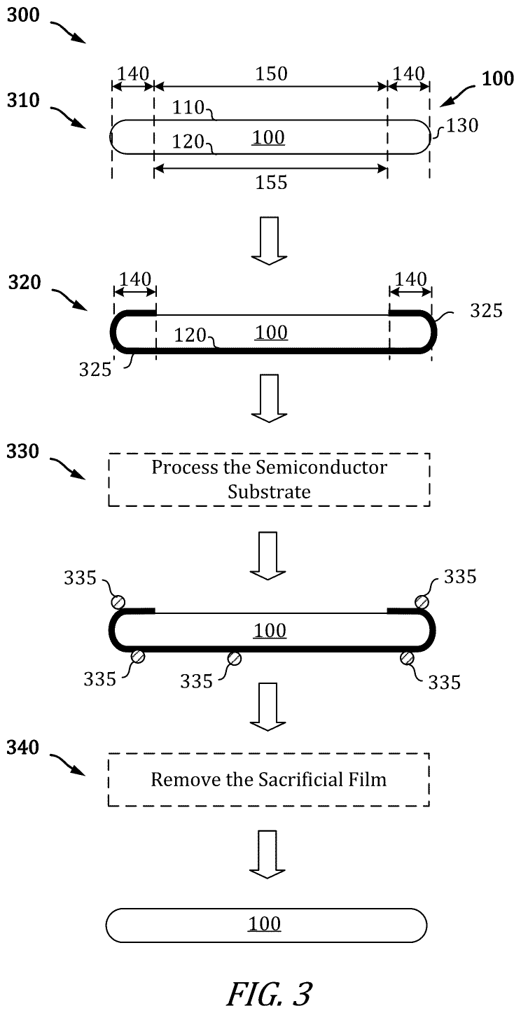

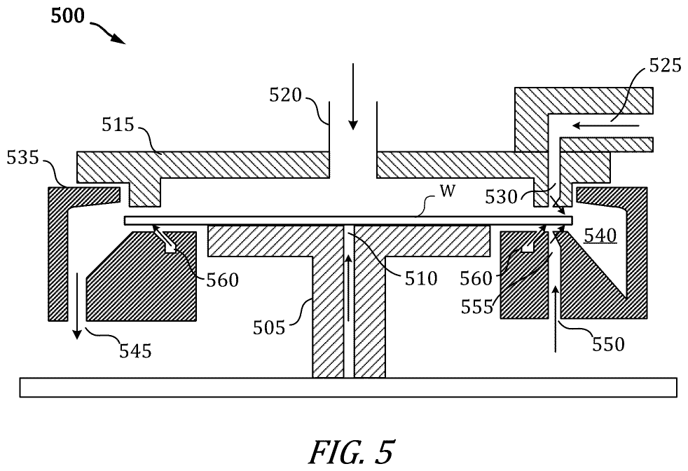

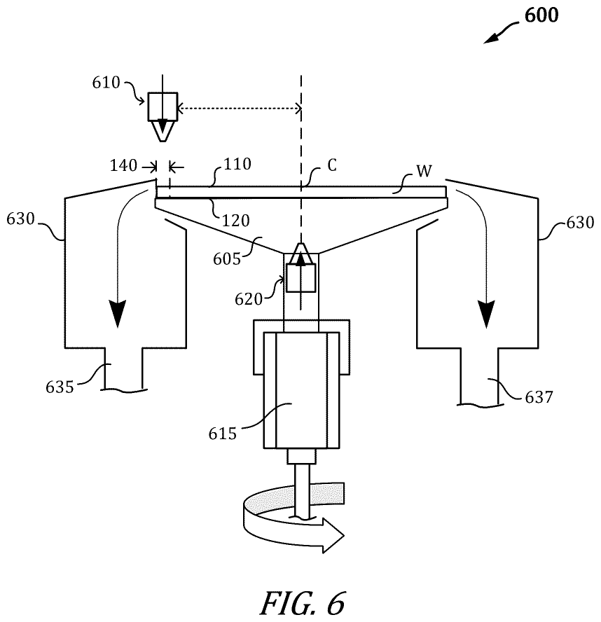

FIG. 3 illustrates one embodiment of a process flow 300 that utilizes the techniques described herein to process a semiconductor substrate, such as the semiconductor substrate 100 shown in FIGS. 1A-1C. More specifically, FIG. 3 illustrates one embodiment of a process flow 300 that utilizes the techniques described herein to prevent damage to, or contamination on, the peripheral edge region and/or along the backside of a semiconductor substrate as the frontside of the substrate undergoes processing. The process flow 300 shown in FIG. 3 may be performed within one or more semiconductor processing chambers. Examples of processing chambers that may be utilized to perform at least one of the steps shown in FIG. 3 are shown in FIGS. 5 and 6 and described in more detail below. It is recognized, however, that the processing chambers shown and described herein are exemplary and that the process flow 300 may be alternatively performed within other semiconductor processing chambers and systems, as is known in the art.

The process flow 300 begins by receiving a semiconductor substrate (or wafer, W) in step 310. The semiconductor substrate received in step 310 may generally include a frontside surface 110, a backside surface 120, a side edge surface 130, a peripheral edge region 140, a frontside center region 150 and a backside center region 155, as shown in FIGS. 1A-1C and discussed above. After receiving the semiconductor substrate in step 310, the process flow 300 may spin-on deposit a sacrificial film 325 within the peripheral edge region 140 and/or along the backside surface 120 of the semiconductor substrate (in step 320).

In some embodiments, the sacrificial film 325 may be spin-on deposited only within the peripheral edge region 140 of the semiconductor substrate in step 320, leaving the frontside center region 150 and the backside center region 155 free of sacrificial film material. In such embodiments, the width of the sacrificial film 325 deposited onto the frontside surface 110 and the backside surface 120 may be approximately equal to the width (w) of the outer annular portions, which as noted above, may range between approximately 1-5 mm. In other embodiments, the sacrificial film 325 may be spin-on deposited within the peripheral edge region 140, and along the backside surface 120 of the semiconductor substrate, leaving only the frontside center region 150 free of sacrificial film material, as shown in FIG. 3. In such embodiments, the sacrificial film 325 completely covers the backside surface 120 of the semiconductor substrate, the side edge surface 130 and approximately 1-5 mm of the outer annular portion on the frontside surface 110. The sacrificial film 325 may be deposited to a thickness ranging from a few monolayers to a few microns, depending on the sacrificial film material utilized.

The sacrificial film 325 is deposited in step 320 via a spin-on deposition process. Unlike other spin-on processes used to deposit thin films, a spin-on deposition process is used herein to coat the peripheral edge region 140 with the sacrificial film, including the side edge surface 130 and the outer annular portions of the frontside surface 110 and the backside surface 120 of the semiconductor substrate 100. In some embodiments, the spin-on deposition process may also coat a portion, or an entirety, of the backside surface 120.

The sacrificial film 325 is spin-on deposited (in step 320) by dispensing a liquid material onto the semiconductor substrate 100 while spinning the semiconductor substrate at a rotational speed, which causes the liquid material to cover the peripheral edge region 140 and/or the backside surface 120 of the semiconductor substrate 100. After dispensing the liquid material, the semiconductor substrate 100 is heat treated (e.g., baked with direct or indirect heating) to solidify the liquid material and form the sacrificial film 325 within the peripheral edge region 140 and/or along the backside surface 120.

A wide variety of liquid materials may be spin-on deposited within the peripheral edge region 140 and/or along the backside surface 120 of the semiconductor substrate in step 320 to form the sacrificial film 325. Examples of liquid materials include, but are not limited to, fluoropolymer materials (e.g., a polytetrafluorethylene (PTFE) or perfluoroalkoxy (PFA) material), spin-on metal materials (such as, e.g., zirconium oxide (ZrOx) and titanium oxide (TiOx)), spin-on glass (SOG) materials, spin-on carbon (SOC) materials and spin-on silicon carbide (SiC) materials.

Once formed, the sacrificial film 325 may protect the peripheral edge region 140 and/or the backside surface 120 from damage or contamination that could occur within these regions during subsequent processing step(s). The sacrificial film material chosen to protect the peripheral edge region 140 and/or the backside surface 120 may generally depend on the process performed. In general, the sacrificial film material is preferably one, which is not etched, dissolved or otherwise removed during a subsequent processing step. In other words, the sacrificial film material is one which is compatible with the subsequent processing step.

As shown in FIG. 3, process flow 300 may process the semiconductor substrate 100 (in step 330) after spin-on depositing the sacrificial film 325 within the peripheral edge region 140 and/or along the backside surface 120 of the semiconductor substrate 100 (in step 320). A wide variety of processes can be performed on the semiconductor substrate 100 in step 330. For example, an etch process, deposition process, lithography process, CMP process, etc., can be performed on the frontside of the substrate in step 330. Other processes may also be performed, as is known in the art. The sacrificial film 325 deposited in step 320 protects the peripheral edge region 140 and/or the backside surface 120 from damage or contamination (represented by dots 335) that could occur during the processing step 330.

In some embodiments, the semiconductor substrate 100 may be processed (in step 330) by providing the semiconductor substrate 100 within a processing chamber having a chuck configured to support one or more surfaces of the substrate, such as a mechanical chuck, an electrostatic chuck or a vacuum chuck. As noted above, electrostatic and vacuum chucks may damage the backside surface 120 of the semiconductor substrate 100 when the substrate is removed from the chuck. By depositing a sacrificial film 325 along the backside surface 120 of the semiconductor substrate 100, the sacrificial film 325 protects the backside surface 120 from damage caused by the chuck.

In some embodiments, the semiconductor substrate 100 may be processed (in step 330) by etching an exposed surface of at least one material layer provided within the frontside center region 150 of the semiconductor substrate 100 using a wet or dry etch process, which exposes the frontside center region 150 and the peripheral edge region 140 of the semiconductor substrate 100 to an etchant chemical or gas. In such embodiments, the sacrificial film 325 may act as a hard mask to protect the peripheral edge region 140 of the semiconductor substrate 100 from being etched by the etchant chemical or gas during the wet or dry etch process.

The sacrificial film material chosen to protect the peripheral edge region 140 during the wet or dry etch process may generally depend on the etchant chemical(s) or gas(es) used during the wet or dry etch process. For example, a spin-on glass (SOG) or spin-on carbon (SOC) material may be used as a sacrificial film 325 to protect the peripheral edge region 140 from etch gases (e.g., sulfur hexafluoride (SF₆), nitrogen trifluoride (NF3) or chlorine (Cl₂) gases) commonly used to etch TSVs through silicon wafers. SOG and SOC materials exhibit low etch rates when exposed to TSV etch gases and are easily removed by wet chemicals, such as SPM and HF. However, other sacrificial film materials, such as fluoropolymer materials, spin-on metal materials and spin-on silicon carbide (SiC) materials, can also be used depending on the etchant chemical(s) or gas(es) used during the wet or dry etch process.

In some embodiments, the semiconductor substrate 100 may be processed (in step 330) by depositing at least one material layer within the frontside center region 150 of the semiconductor substrate 100 using a dry deposition process (e.g., a CVD or ALD process), which exposes the frontside center region 150 and the peripheral edge region 140 of the semiconductor substrate 100 to at least one process gas. In such embodiments, the sacrificial film 325 deposited within the peripheral edge region 140 and/or along the backside surface 120 of the semiconductor substrate 100 may protect the peripheral edge region 140 and/or the backside surface 120 from gas particles that may adhere to the sacrificial film 325 during the dry deposition process. Examples of sacrificial film materials that can be used to protect the peripheral edge region 140 and/or the backside surface 120 from contamination include, but are not limited to, fluoropolymer materials, spin-on metal materials, spin-on glass (SOG) materials, spin-on carbon (SOC) materials and spin-on silicon carbide (SiC) materials.

After the semiconductor substrate 100 is processed (in step 330), the process flow 300 may remove the sacrificial film 325 from the peripheral edge region 140 and/or the backside surface 120 of the semiconductor substrate 100 (in step 340). For example, the sacrificial film 325 may be removed (in step 340) by dispensing a cleaning solution onto the peripheral edge region 140 and/or the backside surface 120 of the semiconductor substrate 100 to remove the sacrificial film. The cleaning solution may be dispensed onto the semiconductor substrate 100 while the substrate is spinning at a rotational speed. Examples of processing chambers that can be used to dispense a cleaning solution onto the peripheral edge region 140 and/or the backside surface 120 of the semiconductor substrate 100 are shown in FIGS. 5 and 6. A wide variety of cleaning solutions can be dispensed in step 340. For example, a variety of solutions may be utilized in step 340, including an ammonia/peroxide mixture (APM), a hydrochloric/peroxide mixture (HPM) and/or a sulfuric peroxide mixture (SPM). Other cleaning solutions may also be utilized in step 340 depending on the sacrificial film material to be removed, as is known in the art. In one example, a dilute hydrofluoric (HF) acid solution may be used to remove the sacrificial film in step 340 when the sacrificial film comprises an SOG material.

As noted above, spin-on deposition processes dispense liquid materials onto a surface of a semiconductor substrate while the substrate is rotating or spinning at a specified rotational speed. In spin-on deposition processes, the liquid materials are dispensed from one or more nozzles, which may be configured to spray a desired quantity of liquid onto the substrate surface in the form of a mist, or drop a specific quantity of liquid onto the substrate surface. The nozzle(s) may be fixed or movable and can be positioned above and/or below the substrate surface, depending on the surface(s) desired to be coated with the liquid.

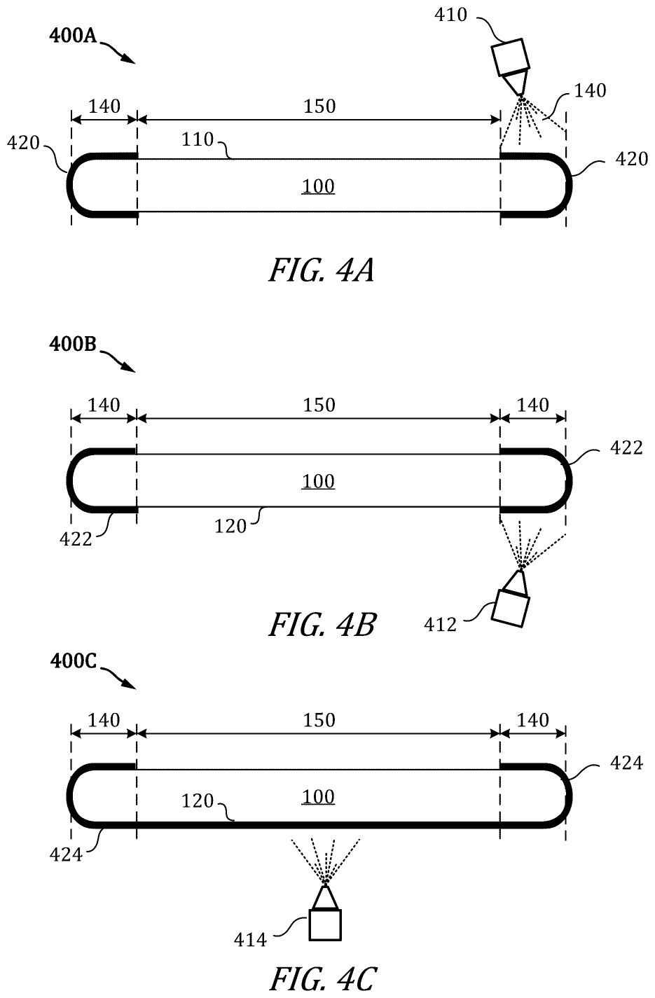

A variety of nozzles can be used to spin-on deposit the sacrificial film 325 within the peripheral edge region 140 and/or along the backside surface 120 of the substrate. In the embodiment 400A shown in FIG. 4A, for example, a frontside bevel nozzle 410 is used to deposit a sacrificial film 420 within the peripheral edge region 140 of the substrate 100. As shown in FIG. 4A, the frontside bevel nozzle 410 is positioned above the bevel region on the frontside surface 110 of the semiconductor substrate 100. In some embodiments, the frontside bevel nozzle 410 may be used to dispense a liquid material onto the outer annular portion of the frontside surface 110, while the semiconductor substrate 100 is spinning at a rotational speed (e.g., 200 to 3000 RPM), to deposit the sacrificial film 420 within the peripheral edge region 140 of the substrate 100. The rotational speed of the substrate 100 causes the liquid material dispensed onto the outer annular portion of the frontside surface 110 to wrap around the side edge surface 130 of the semiconductor substrate 100 and at least partially coat the outside annular portion of the backside surface 120 with the sacrificial film 420. The degree of wrap-around depends on the viscosity of the liquid material and the rotational speed of the substrate 100. In some embodiments, the rotational speed of the semiconductor substrate 100 can be adjusted to achieve a desired wrap-around for a given liquid material.

In other embodiments, a backside bevel nozzle 412 may be used to deposit a sacrificial film 422 within the peripheral edge region 140 of the substrate 100, as shown in the embodiment 400B depicted in FIG. 4B. The backside bevel nozzle 412 is positioned below the bevel region on the backside surface 120 of the semiconductor substrate 100. In some embodiments, the backside bevel nozzle 412 may be used to dispense a liquid material onto the outer annular portion of the backside surface 120, while the semiconductor substrate 100 is spinning at a rotational speed (e.g., 200 to 3000 RPM), to deposit the sacrificial film 422 within the peripheral edge region 140 of the substrate 100. The rotational speed of the substrate 100 causes the liquid material dispensed onto the outer annular portion of the backside surface 120 to wrap around the side edge surface 130 of the semiconductor substrate 100 and at least partially coat the outside annular portion of the frontside surface 110 with the sacrificial film 422. As with the previous embodiment, the degree of wrap around may generally depend on the viscosity of the liquid material and the rotational speed of the substrate 100.

In yet other embodiments, a backside nozzle 414 may be used to deposit a sacrificial film 424 within the peripheral edge region 140 of the substrate 100, as shown in the embodiment 400C depicted in FIG. 4C. The backside nozzle 414 is positioned below the backside surface 120 near the center of the semiconductor substrate 100. In some embodiments, the backside nozzle 414 may be utilized to dispense a liquid material onto the backside surface 120 of the semiconductor substrate 100 near the center of the substrate 100 while the substrate 100 is spinning at a rotational speed (e.g., 200 to 3000 RPM), to deposit the sacrificial film 424 within the peripheral edge region 140 of the substrate 100. The rotational speed of the substrate 100 causes the liquid material dispensed onto the backside surface 120 to completely cover the backside surface 120 and wrap around the side edge surface 130 to at least partially coat the outside annular portion of the frontside surface 110 with the sacrificial film 424. Again, the degree of wrap-around may depend on the viscosity of the liquid material and the rotational speed of the substrate 100.

FIG. 5 illustrates one example of a processing chamber 500 that can be used to spin-on deposit a sacrificial film (e.g., the sacrificial film 420 or 422) onto a peripheral edge region 140 of a semiconductor substrate 100, as shown in FIGS. 4A-4B. In the processing chamber 500 shown in FIG. 5, a semiconductor substrate (W) is mounted frontside up on a spin chuck 505 and held in place, for example, by a vacuum pressure provided via the central path 510 through the spin chuck 505. During various processing steps, the spin chuck 505 is rotated at an angular velocity by a drive mechanism (not shown), which causes the spin chuck 505 and the semiconductor substrate W mounted thereon to spin at a variety of rotational speeds.

In addition to spin chuck 505, processing chamber 500 includes various nozzles for dispensing liquids onto one or more surfaces of the semiconductor substrate W. The nozzle(s) may be configured to dispense liquids onto the substrate surface(s), while the semiconductor substrate W is spinning at a variety of rotational speeds. In some embodiments, one or more of the nozzles may be used to dispense a liquid material onto one or more surfaces of the semiconductor substrate W, while the substrate is spinning at a specified rotational speed (e.g., 200 to 3000 RPM), to spin-on deposit a sacrificial film onto the peripheral edge region of the semiconductor substrate W.

As shown in FIG. 5, the processing chamber 500 includes a top cover 515, which is positioned above the spin chuck 505 and the semiconductor substrate W mounted thereon. The top cover 515 includes an air inlet 520 for supplying clean, dry air to the semiconductor substrate W, and a liquid supply line 525 and frontside bevel nozzle 530 for supplying various liquids to the substrate surface. As shown in FIGS. 4A and 5, the frontside bevel nozzle 410/530 is positioned above the bevel region on the frontside surface 110 of the semiconductor substrate 100. In some embodiments, the frontside bevel nozzle 410/530 may be used to dispense a liquid material onto the outer annular portion of the frontside surface 110 of the semiconductor substrate 100, while the substrate is spinning at the specified rotational speed, to form the sacrificial film 420 within the peripheral edge region 140 of the substrate 100, as shown in FIG. 4A.

A drain cup 535 is provided within the processing chamber 500 to capture liquids, which are ejected from the surface of the semiconductor substrate W by the centrifugal forces generated during rotation of the spin chuck 505. The liquids ejected from the substrate surface are collected within a reservoir 540 provided within the drain cup 535 and drained via a drain line 545 and drain unit (not shown). In some embodiments, an exhaust line and exhaust unit (not shown) may be provided within the processing chamber 500 to remove gaseous species from the processing space inside the drain cup 535.

In some embodiments, a liquid supply line 550 and backside bevel nozzle 555 may be provided for supplying various liquids to the substrate surface. As shown in FIGS. 4B and 5, the backside bevel nozzle 412/555 is positioned below the bevel region on the backside surface 120 of the semiconductor substrate 100. In some embodiments, the backside bevel nozzle 412/555 may be used to dispense a liquid material onto the outer annular portion of the backside surface 120 of the semiconductor substrate 100, while the substrate is spinning at the specified rotational speed, to form the sacrificial film 422 within the peripheral edge region 140 of the substrate 100, as shown in FIG. 4B. The drain cup 535 may additionally include one or more gas nozzles 560 for supplying various gases (e.g., purge gases, such as nitrogen) to the backside bevel region.

FIG. 6 illustrates another example of a processing chamber 600 that can be used to spin-on deposit a sacrificial film (e.g., the sacrificial film 420, 422 or 424) onto a peripheral edge region 140 and/or along a backside surface 120 of a semiconductor substrate 100, as shown in FIGS. 4A-4C. The processing chamber 600 shown in FIG. 6 includes a spin chuck 605 (e.g., a mechanical chuck) for holding a semiconductor substrate (W) thereon, a drive mechanism 615 for rotating the spin chuck 605 at a variety of rotational speeds, a pair of nozzles 610 and 620 for dispensing liquids onto one or more surfaces of the substrate W and a cup 630 for capturing liquids, which are ejected from the surface of the substrate W by the centrifugal forces generated during rotation of the spin chuck 605. As shown in FIG. 6, the cup 630 may include a drain line 635 and drain unit (not shown) for draining liquids ejected from the substrate surface, and an exhaust line 637 and exhaust unit (not shown) for removing gaseous species from the processing space inside the cup 630.

In the embodiment shown in FIG. 6, the processing chamber 600 includes a frontside nozzle 610 and a backside nozzle 620. The frontside nozzle 610 is positioned above the semiconductor substrate W for dispensing processing liquids onto the frontside surface 110 of the substrate W, and is translatable between a center (C) and peripheral edge region 140 of the substrate W. The backside nozzle 620 is provided within a central region of the spin chuck 605 for dispensing processing liquids onto the backside surface 120 of the substrate W. The nozzles 610 and 620 may dispense liquids onto one or more surfaces of the semiconductor substrate W, while the substrate W is spinning at a specified rotational speed.

The nozzles 610 and 620 may be used to dispense a wide variety of liquids onto the surface(s) of the semiconductor substrate W, depending on the process(es) being performed within the processing chamber 600. In some embodiments, nozzle 610 may dispense a liquid material onto the peripheral edge region 140 of the substrate W, while the spin chuck 605 spins the substrate W at a specified rotational speed, to coat the peripheral edge region 140 with the liquid material and form the sacrificial film 420, as shown in FIG. 4A. In other embodiments, nozzle 620 may dispense a liquid material onto the backside surface 120 of the substrate W, while the spin chuck 605 spins the substrate W at a specified rotational speed, to coat the backside surface 120 and the peripheral edge region 140 with the liquid material and form the sacrificial film 424, as shown in FIG. 4C.

The nozzles 610 and 620 can also be used to dispense other processing liquids onto the substrate. In one example, the nozzles 610 and 620 may dispense a cleaning solution, a rinsing solvent and/or a drying solvent onto one or more surfaces of the substrate W when performing a cleaning process within the processing chamber 600. In another example, the nozzles 610 and 620 may dispense a coating material (e.g., a photoresist) and a developer solvent onto one or more surfaces of the substrate W when performing a photoresist patterning process. In another example, the nozzles 610 and 620 may dispense an etchant chemical onto one or more surfaces of the substrate W when a wet etching process is performed. Other processing liquids may be dispensed onto the surface(s) of the substrate W when performing other processes within the processing chamber 600, as is known in the art.

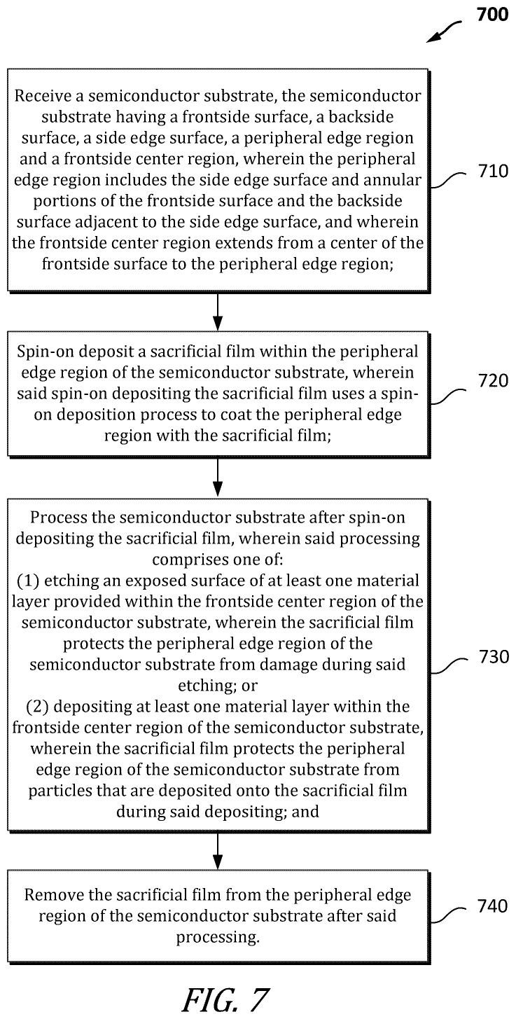

FIGS. 7-9 illustrate various embodiments of methods that utilize the techniques described herein to process a semiconductor substrate, such as the semiconductor substrate 100 shown in FIGS. 1A-1C. It will be recognized that the embodiments of FIGS. 7-9 are merely exemplary and additional methods may utilize the techniques described herein. Further, additional processing steps may be added to the methods shown in the FIGS. 7-9 as the steps described are not intended to be exclusive. Moreover, the order of the steps is not limited to the order shown in the figures as different orders may occur and/or various steps may be performed in combination or at the same time.

The methods shown in FIGS. 7-9 may generally be performed within one or more semiconductor processing chambers. For example, at least one of the method steps shown in FIGS. 7-9 (e.g., the spin-on deposition step) may be performed within a wet processing chamber, such as the processing chambers 500 and 600 shown in FIGS. 5 and 6. It is recognized, however, that the processing chambers shown and described herein are exemplary and that the various method steps may be performed within other semiconductor processing chambers and systems, as is known in the art.

FIG. 7 illustrates one embodiment of a method 700 that utilizes the techniques described herein to process a semiconductor substrate. More specifically, FIG. 7 illustrates one embodiment of a method 700 that utilizes a sacrificial film to protect the peripheral edge region of a semiconductor substrate during an etch or deposition process.

The method 700 shown in FIG. 7 begins (in step 710) by receiving a semiconductor substrate 100 having a frontside surface 110, a backside surface 120, a side edge surface 130, a peripheral edge region 140 and a frontside center region 150. As shown in FIGS. 1A-1C and described above, the peripheral edge region 140 includes the side edge surface 130 and annular portions of the frontside surface 110 and the backside surface 120 adjacent to the side edge surface 130. The frontside center region 150 extends from a center (c) of frontside surface 110 to the peripheral edge region 140. The method 700 further includes spin-on depositing a sacrificial film within the peripheral edge region 140 of the semiconductor substrate 100 (in step 720). In the method 700, a spin-on deposition process is used to coat the peripheral edge region 140 with the sacrificial film. The sacrificial film can be spin-on deposited in step 720 using a wide variety of processing chambers and nozzle configurations, as shown in FIGS. 4-6 and described above.

The method 700 further includes processing the semiconductor substrate 100 after spin-on depositing the sacrificial film (in step 730). In the embodiment shown in FIG. 7, the semiconductor substrate 100 is processed in step 730 by either: (1) etching an exposed surface of at least one material layer provided within the frontside center region 150 of the semiconductor substrate, or (2) depositing at least one material layer within the frontside center region 150 of the semiconductor substrate 100. Thus, in the embodiment shown in FIG. 7, the sacrificial film deposited in step 720 may function to protect the peripheral edge region 140 of the semiconductor substrate 100 from damage during etching, or particles deposited onto the sacrificial film during depositing. After processing the semiconductor substrate 100 in step 730, the method 700 removes the sacrificial film from the peripheral edge region 140 in step 740.

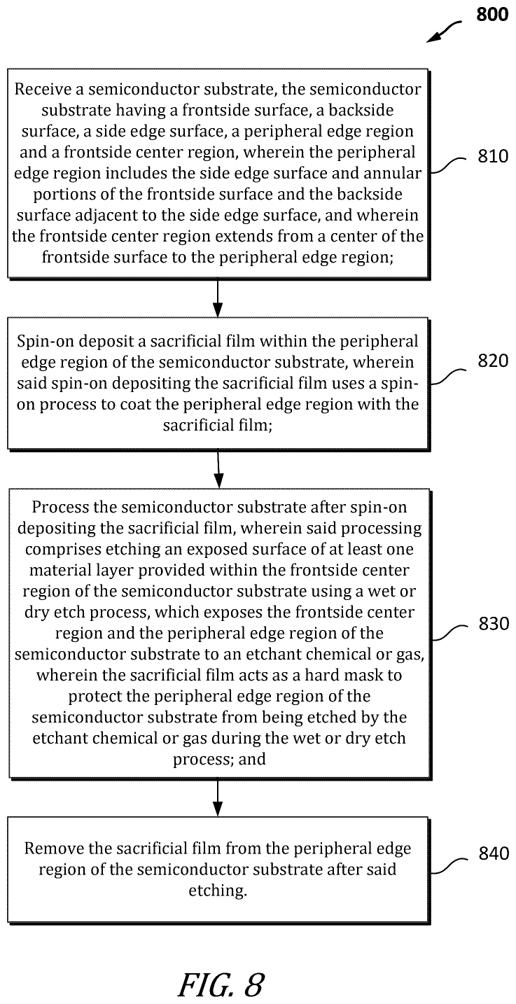

FIG. 8 illustrates another embodiment of a method 800 that utilizes the techniques described herein to process a semiconductor substrate. More specifically, FIG. 8 illustrates a method 800 that uses a sacrificial film to prevent damage to the peripheral edge region of a semiconductor substrate as the frontside of the substrate undergoes an etch process.

The method 800 shown in FIG. 8 begins (in step 810) by receiving a semiconductor substrate 100 having a frontside surface 110, a backside surface 120, a side edge surface 130, a peripheral edge region 140 and a frontside center region 150. As shown in FIGS. 1A-1C and described above, the peripheral edge region 140 includes the side edge surface 130 and annular portions of the frontside surface 110 and the backside surface 120 adjacent to the side edge surface 130. The frontside center region 150 extends from a center (c) of frontside surface 110 to the peripheral edge region 140. The method 800 further includes spin-on depositing a sacrificial film within the peripheral edge region 140 of the semiconductor substrate 100 (in step 820). In the method 800, a spin-on deposition process is used to coat the peripheral edge region 140 with the sacrificial film. The sacrificial film can be spin-on deposited in step 820 using a wide variety of processing chambers and nozzle configurations, as shown in FIGS. 4-6 and described above.

The method 800 further includes processing the semiconductor substrate 100 after spin-on depositing the sacrificial film (in step 830). In the embodiment shown in FIG. 8, the semiconductor substrate 100 is processed in step 830 by etching an exposed surface of at least one material layer provided within the frontside center region 150 of the semiconductor substrate 100 using a wet or dry etch process, which exposes the frontside center region 150 and the peripheral edge region 140 of the semiconductor substrate 100 to an etchant chemical or gas. Thus, in the embodiment shown in FIG. 8, the sacrificial film deposited in step 820 acts as a hard mask to protect the peripheral edge region 140 of the semiconductor substrate 100 from being etched by the etchant chemical or gas during the wet or dry etch process. After etching the semiconductor substrate 100 in step 830, the method 800 removes the sacrificial film from the peripheral edge region 140 in step 840.

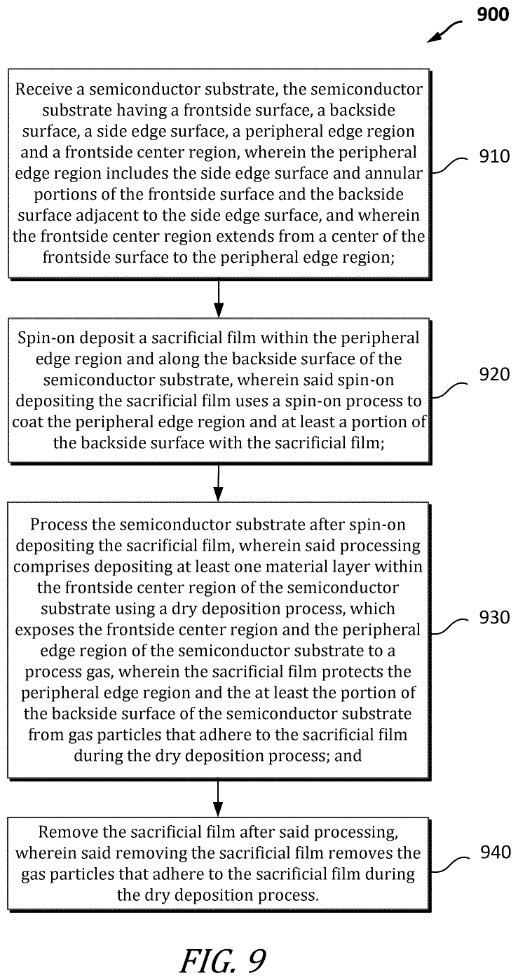

FIG. 9 illustrates another embodiment of a method 900 that utilizes the techniques described herein to process a semiconductor substrate. More specifically, FIG. 9 illustrates a method 900 that uses a sacrificial film to prevent contamination on the peripheral edge region and along the backside of a semiconductor substrate as the frontside of the substrate undergoes a deposition process.

The method 900 shown in FIG. 9 begins (in step 910) by receiving a semiconductor substrate 100 having a frontside surface 110, a backside surface 120, a side edge surface 130, a peripheral edge region 140 and a frontside center region 150. As shown in FIGS. 1A-1C and described above, the peripheral edge region 140 includes the side edge surface 130 and annular portions of the frontside surface 110 and the backside surface 120 adjacent to the side edge surface 130. The frontside center region 150 extends from a center (c) of frontside surface 110 to the peripheral edge region 140. The method 900 further includes spin-on depositing a sacrificial film within the peripheral edge region 140 and along the backside surface 120 of the semiconductor substrate 100 (in step 920). In the method 900, a spin-on deposition process is used to coat the peripheral edge region 140 and at least a portion of the backside surface 120 with the sacrificial film. The sacrificial film can be spin-on deposited in step 920 using a wide variety processing chambers and nozzle configurations, as shown in FIGS. 4-6 and described above.

The method 900 further includes processing the semiconductor substrate 100 after spin-on depositing the sacrificial film (in step 930). In the embodiment shown in FIG. 9, the semiconductor substrate 100 is processed in step 930 by depositing at least one material layer within the frontside center region 150 of the semiconductor substrate 100 using a dry deposition process, which exposes the frontside center region 150 and the peripheral edge region 140 of the semiconductor substrate 100 to a process gas. Thus, in the embodiment shown in FIG. 9, the sacrificial film deposited in step 920 protects the peripheral edge region 140 and at least the portion of the backside surface 120 of the semiconductor substrate 100 from gas particles that adhere to the sacrificial film during the dry deposition process. In step 940, the method 900 removes the sacrificial film from the peripheral edge region 140 and the backside surface 120, wherein said removing removes any gas particles that adhere to the sacrificial film during the dry deposition process. In doing so, the method 900 prevents contamination from accumulating on the peripheral edge region 140 and the backside surface 120.

Systems and methods for processing a substrate are described in various embodiments. The substrate may include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the systems and methods described herein will be apparent to those skilled in the art in view of this description. It will be recognized, therefore, that the described systems and methods are not limited by these example arrangements. It is to be understood that the forms of the systems and methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for processing a semiconductor substrate, the method comprising:
receiving the semiconductor substrate, the semiconductor substrate having a frontside surface, a backside surface, a side edge surface, a peripheral edge region and a frontside center region, wherein the peripheral edge region includes the side edge surface and annular portions of the frontside surface and the backside surface adjacent to the side edge surface, and wherein the frontside center region extends from a center of frontside surface to the peripheral edge region;
spin-on depositing a sacrificial film within the peripheral edge region of the semiconductor substrate, wherein said spin-on depositing the sacrificial film uses a spin-on deposition process to coat the peripheral edge region with the sacrificial film; and
processing the semiconductor substrate after spin-on depositing the sacrificial film, wherein said processing comprises one of:
(1) etching an exposed surface of at least one material layer provided within the frontside center region of the semiconductor substrate, wherein the sacrificial film protects the peripheral edge region of the semiconductor substrate from damage during said etching; or
(2) depositing at least one material layer within the frontside center region of the semiconductor substrate, wherein the sacrificial film protects the peripheral edge region of the semiconductor substrate from particles that are deposited onto the sacrificial film during said depositing.

2. The method of claim 1, wherein said spin-on depositing the sacrificial film comprises dispensing a liquid material within the peripheral edge region of the semiconductor substrate that is not removed during said processing.

3. The method of claim 2, wherein said dispensing the liquid material comprises dispensing a fluoropolymer material, a spin-on metal material, a spin-on glass (SOG) material, a spin-on carbon (SOC) material or a spin-on silicon carbide (SiC) material within the peripheral edge region of the semiconductor substrate.

4. The method of claim 2, wherein said dispensing the liquid material is performed within a processing chamber comprising a frontside bevel nozzle, and wherein said dispensing the liquid material comprises:
using the frontside bevel nozzle to dispense the liquid material onto the annular portion of the frontside surface while spinning the semiconductor substrate at a rotational speed, which causes the liquid material to wrap around the side edge surface of the semiconductor substrate to coat the annular portion of the backside surface.

5. The method of claim 2, wherein said dispensing the liquid material is performed within a processing chamber comprising a backside bevel nozzle, and wherein said dispensing the liquid material comprises:
using the backside bevel nozzle to dispense the liquid material onto the annular portion of the backside surface while spinning the semiconductor substrate at a rotational speed, which causes the liquid material to wrap around the side edge surface of the semiconductor substrate to coat the annular portion of the frontside surface.

6. The method of claim 2, wherein said spin-on depositing the sacrificial film comprises dispensing the liquid material within the peripheral edge region and on the backside surface of the semiconductor substrate.

7. The method of claim 6, wherein said dispensing the liquid material comprises dispensing a fluoropolymer material, a spin-on metal material, a spin-on glass (SOG) material, a spin-on carbon (SOC) material or a spin-on silicon carbide (SiC) material within the peripheral edge region and on the backside surface of the semiconductor substrate.

8. The method of claim 6, wherein said dispensing the liquid material is performed within a processing chamber comprising a backside nozzle, and wherein said dispensing the material comprises:
using the backside nozzle to dispense the liquid material onto the backside surface of the semiconductor substrate near the center of the semiconductor substrate while spinning the semiconductor substrate at a rotational speed, which causes the liquid material to cover the backside surface and wrap around the side edge surface of the semiconductor substrate to coat the annular portion of the frontside surface.

9. The method of claim 6, wherein said processing the semiconductor substrate comprises:
providing the semiconductor substrate within a processing chamber having a chuck configured to support one or more surfaces of the semiconductor substrate; and
wherein the sacrificial film protects the peripheral edge region and/or the backside surface of the semiconductor substrate from damage caused by the chuck.

10. The method of claim 1, wherein said processing the semiconductor substrate comprises:
etching the exposed surface of the at least one material layer provided within the frontside center region of the semiconductor substrate using a wet or dry etch process, which exposes the frontside center region and the peripheral edge region of the semiconductor substrate to an etchant chemical or gas; and
wherein the sacrificial film acts as a hard mask to protect the peripheral edge region of the semiconductor substrate from being etched by the etchant chemical or gas during the wet or dry etch process.

11. The method of claim 10, wherein said spin-on depositing the sacrificial film comprises dispensing a liquid material within the peripheral edge region of the semiconductor substrate that is not removed by the etchant chemical or gas.

12. The method of claim 11, wherein said dispensing the liquid material comprises dispensing a fluoropolymer material, a spin-on metal material, a spin-on glass (SOG) material, a spin-on carbon (SOC) material or a spin-on silicon carbide (SiC) material within the peripheral edge region of the semiconductor substrate.

13. The method of claim 10, further comprising removing the sacrificial film from the peripheral edge region of the semiconductor substrate after said etching.

14. The method of claim 13, wherein said removing the sacrificial film comprises dispensing a cleaning solution onto the semiconductor substrate to remove the sacrificial film from the peripheral edge region.

15. The method of claim 1, wherein said processing the semiconductor substrate comprises:
depositing the at least one material layer within the frontside center region of the semiconductor substrate using a dry deposition process, which exposes the frontside center region and the peripheral edge region of the semiconductor substrate to a process gas; and
wherein the sacrificial film protects the peripheral edge region of the semiconductor substrate from gas particles that adhere to the sacrificial film during the dry deposition process.

16. The method of claim 15, wherein said spin-on depositing the sacrificial film comprises dispensing a liquid material within the peripheral edge region and at least a portion of the backside surface of the semiconductor substrate.

17. The method of claim 16, wherein said dispensing the liquid material comprises dispensing a fluoropolymer material, a spin-on metal material, a spin-on glass (SOG) material, a spin-on carbon (SOC) material or a spin-on silicon carbide (SiC) material within the peripheral edge region and on the at least a portion of the backside surface of the semiconductor substrate.

18. The method of claim 15, wherein said spin-on depositing the sacrificial film comprises:
dispensing a liquid material onto the semiconductor substrate while spinning the semiconductor substrate at a rotational speed, which causes the liquid material to cover the peripheral edge region and at least a portion of the backside surface of the semiconductor substrate;
heat treating the semiconductor substrate to solidify the liquid material and form the sacrificial film within the peripheral edge region and on the at least a portion of the backside surface; and
wherein the sacrificial film protects the peripheral edge region and the at least a portion of the backside surface of the semiconductor substrate from gas particles that adhere to the sacrificial film during the dry deposition process.

19. The method of claim 15, further comprising removing the sacrificial film and the gas particles that adhere to the sacrificial film during the dry deposition process.

20. The method of claim 19, wherein said removing the sacrificial film comprises dispensing a cleaning solution onto the semiconductor substrate to remove the sacrificial film and the gas particles that adhere to the sacrificial film during the dry deposition process.
